(19) United States
(12) Patent Application Publication
(10) Pub. No.: US 2025/0385168 A1
(43) Pub. Date: Dec. 18, 2025

(54) LOCALIZED THINNED BOARD FOR BOTTOM SIDE COMPONENT INTEGRATION

(71) Applicant: Intel Corporation, Santa Clara, CA (US)

(72) Inventors: Min Suet LIM, Gelugor (MY); Chin Lee KUAN, Bentong (MY); Jeff KU, Taipei City (TW); Pin Jan WANG, Portland, OR (US); Telesphor KAMGAING, Chandler, AZ (US)

(21) Appl. No.: 18/745,782

(22) Filed: Jun. 17, 2024

(51) Int. Cl. H01L 23/498

(52) U.S. Cl. CPC H01L 23/49816; H01L 23/49822

(57) ABSTRACT

Embodiments disclosed herein include an apparatus with a substrate with a first surface and a second surface. In an embodiment, the substrate comprises a dielectric material. A first region of the substrate has a first metal density, and a second region of the substrate has a second metal density, where the second metal density is lower than the first metal density. In an embodiment, a depression is formed into the first surface of the substrate, where the depression is located at least partially over the second region of the substrate.

### BACKGROUND

In electronics packaging, power delivery performance is improved when package landside capacitors are provided within the die shadow so that the capacitors are as close to the load as possible. However, the drive to smaller package form factors has required smaller ball grid array (BGA) pitch and diameter. This has resulted in smaller package to board gap heights. As such, it has become more difficult to include landside capacitors between the package substrate and the board.

### BRIEF DESCRIPTION OF THE DRAWINGS

FIG. 1A is a cross-sectional illustration of an electronic system with a board and a package substrate that comprises a depression for accommodating a component between the package substrate and the board, in accordance with an embodiment.

FIG. 1B is a cross-sectional illustration of an electronic system with a package substrate and a board that comprises a depression for accommodating a component between the board and the package substrate, in accordance with an embodiment.

FIG. 1C is a cross-sectional illustration of an electronic system with a package substrate and a board, where both the package substrate and the board comprise depressions for accommodating a component between the board and the package substrate, in accordance with an embodiment.

FIG. 2A is a cross-sectional illustration of a package substrate with a depression that has sloped sidewalls, in accordance with an embodiment.

FIG. 2B is a cross-sectional illustration of a package substrate with a depression that has vertical sidewalls, in accordance with an embodiment.

FIG. 2C is a cross-sectional illustration of a package substrate with a depression for accommodating a plurality of components, in accordance with an embodiment.

FIG. 2D is a cross-sectional illustration of a package substrate with a plurality of depressions for accommodating a plurality of components, in accordance with an embodiment.

FIGS. 3A-3H are cross-sectional illustrations depicting a process for forming a board with a depression, in accordance with an embodiment.

FIG. 4 is a process flow diagram of a process for forming a substrate with a depression, in accordance with an embodiment.

FIG. 5 is a schematic of a computing device built in accordance with an embodiment.

### EMBODIMENTS OF THE PRESENT DISCLOSURE

Described herein are board and package architectures with thinned regions for bottom side component integration, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

As noted above, the drive to smaller form factors in electronics packaging has reduced the standoff height between the package substrate and the board (e.g., a printed circuit board (PCB)). The decrease in standoff height has made the integration of passive electrical components (e.g., land side capacitors) more difficult. Existing solutions have included the use of cavities or recesses into the package substrate and/or board in order to accommodate the thickness of the passive components. Recesses in the board and/or package substrates are typically formed with a mechanical drilling or laser drilling process. This incurs an additional processing operation and increases the cost of fabrication. In the case of a board, some options also include the formation of holes through the board. This requires double-sided assembly to place an electromagnetic interference (EMI) shield to ground the copper around the hole in the board. This option increases form factor and also increases assembly costs. More generally, the existing solutions rely on the complete buildup of the substrate (either the package substrate or the board), and then portions of the substrate are removed with a subtractive process.

Accordingly, embodiments disclosed herein may include a substrate manufacturing process that inherently forms a recess or depression where the component is desired. In some embodiments, thickness variations attributable to lamination processes and/or conditions can be leveraged over one or more layers in order to provide a recess with a desired depth to accommodate the component. In some instances, the recess is formed by providing non-uniform metal densities under the laminated dielectric layer. For example, a low metal density region will result in a thinner region of the dielectric layer compared to the portion of the dielectric layer over a high metal density region. As one or more dielectric layers with thickness non-uniformity are laminated over each other, a desired depression depth may be provided. As used herein, “metal density” may refer to the proportion of metal within a chosen region relative to other materials. For example, in a cross-sectional view, the metal density of a dielectric layer, of a portion of a dielectric layer, of a plurality of dielectric layers, or of a portion of a plurality of dielectric layers may refer to the proportion of the total area of metal that is visible within the selected portion of the cross-section relative to the total area of the selected portion of the cross-section. As can be appreciated, embodiments disclosed herein do not use subtractive processes in order to form the recess or depression in the substrate (i.e., a package substrate or a board). This reduces at least one processing operation (e.g., drilling, etc.) so the substrate can be manufactured faster, and the cost of manufacturing the substrate is also reduced.

In some embodiments, the package substrate includes a depression and the board is substantially flat. In other embodiments, the package substrate is substantially flat, and the board includes a depression. In yet another embodiment, the package substrate and the board both comprise a depression. The depressions that are formed in the substrate may include a single dielectric layer with a non-uniform thickness or a plurality of dielectric layers with non-uniform thicknesses. The sidewalls of the depression may slope more gradually than a sidewall of a drilled cavity. The depression may also have a curved and/or non-linear profile.

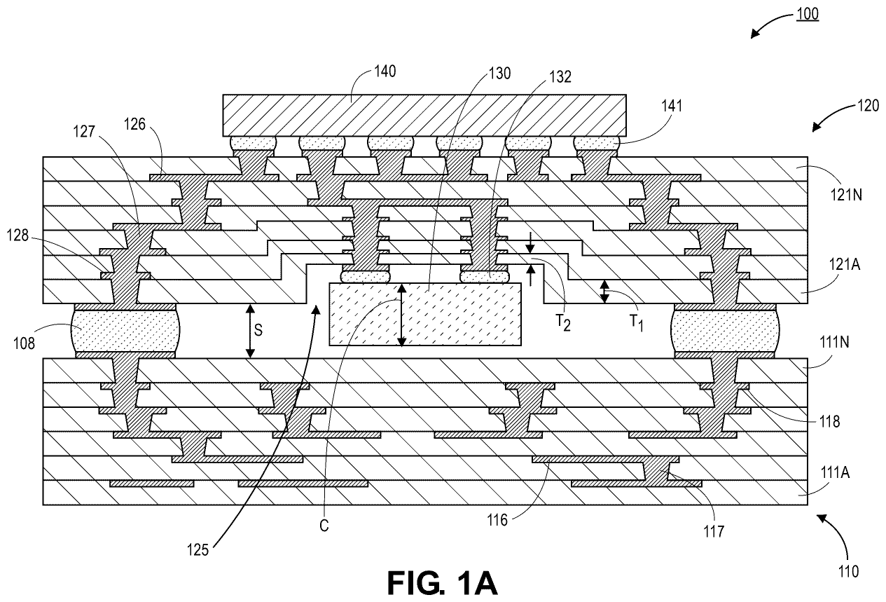

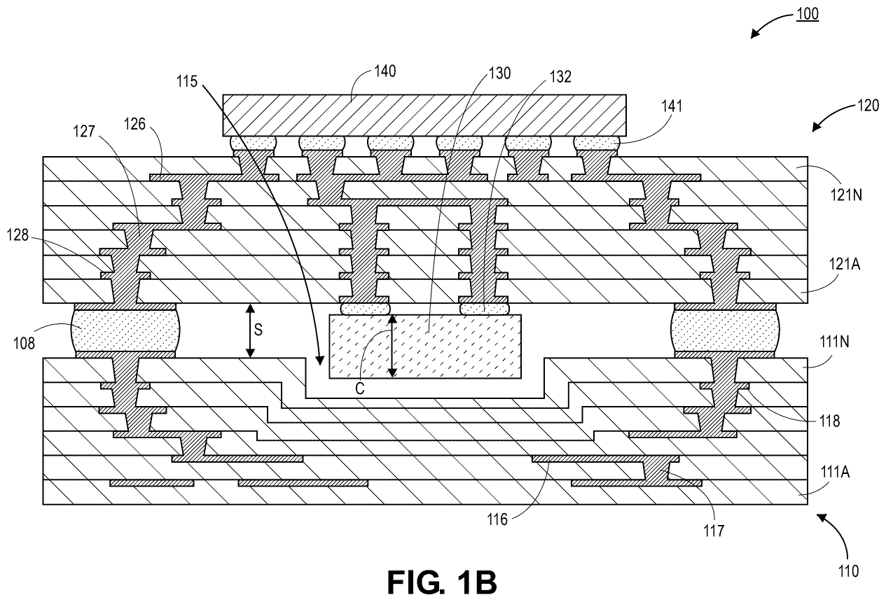

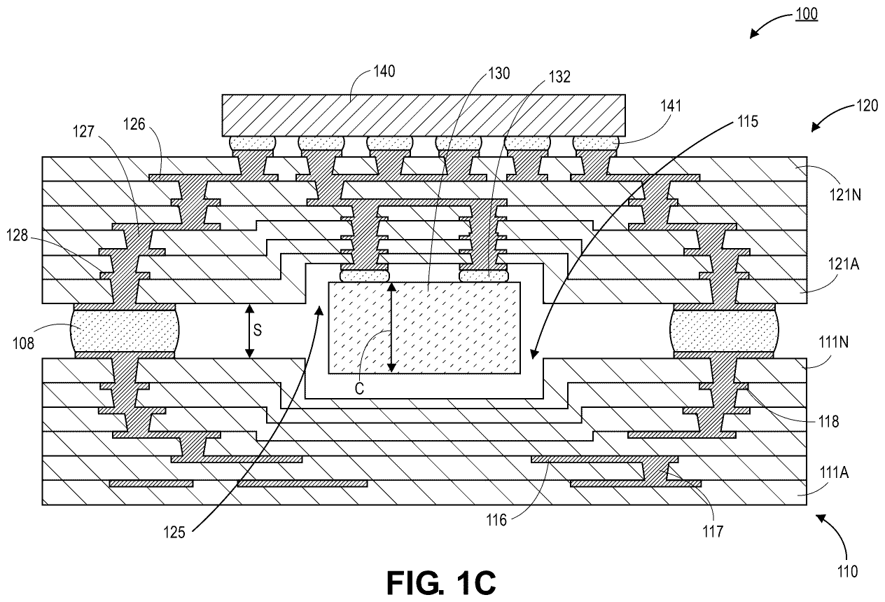

Referring now to FIG. 1A, a cross-sectional illustration of an electronic system 100 is shown, in accordance with an embodiment. The electronic system 100 may comprise a board 110 (e.g., a PCB) and a package substrate 120 coupled to the board 110. The package substrate 120 may be coupled to the board 110 by interconnects 108, such as solder bumps or any other suitable second level interconnect (SLI) architecture. In an embodiment, the interconnects 108 provide a standoff height S between a bottom surface of the package substrate 120 and a top surface of the board 110.

In an embodiment, the board 110 may comprise a plurality of layers 111A-111N. For example, six layers 111 are shown in FIG. 1A. The layers 111 may comprise dielectric material, such as buildup film or the like. The layers 111 may be assembled over each other with a lamination process or the like. In the illustrated embodiment the board 110 is coreless. Though, other embodiments may include a board 110 with a core. The board 110 may comprise electrically conductive routing, such as pads 118, vias 117, and traces 116. The electrically conductive routing may be formed with any suitable plating and/or patterning processes, such as a damascene process, a dual damascene process, or the like.

In an embodiment, the package substrate 120 may comprise a plurality of layers 121A-121N. For example, six layers 121 are shown in FIG. 1A. The layers 121 may comprise dielectric material, such as buildup film or the like. The layers 121 may be assembled over each other with a lamination process or the like. In the illustrated embodiment the package substrate 120 is coreless. Though, other embodiments may include a package substrate 120 with a core (e.g., an organic core, a glass core, or the like). The package substrate 120 may comprise electrically conductive routing, such as pads 128, vias 127, and traces 126. The electrically conductive routing may be formed with any suitable plating and/or patterning processes, such as a damascene process, a dual damascene process, or the like.

In an embodiment, one or more of the layers 121 may have a non-uniform thickness. For example, the layer 121A has a first thickness T₁ towards an edge of the package substrate 120 and a second thickness T₂ towards a center of the package substrate 120. The difference between the first thickness T₁ and the second thickness T₂ may result in the formation of a depression 125 along the bottom surface of the package substrate 120. In an embodiment, the difference between the first thickness T₁ and the second thickness T₂ may be up to 10%, up to 20%, or up to 30%. The depression 125 may also be referred to as a trench, a hole, a cavity, and/or the like in other embodiments. As multiple layers 121 with non-uniform thicknesses are stacked over each other, the depth of the depression 125 increases. For example, three layers 121 include non-uniform thicknesses in FIG. 1A. In an embodiment, a depth of the depression 125 may be approximately 5 μm or more, approximately 10 μm or more, or approximately 20 μm or more. As will be described in greater detail below, the depression 125 may be formed, at least in part, due to metal density differences across each layer 121 of the package substrate 120. For example, within a single layer 121, regions with a relatively low metal density may have a smaller thickness than regions with a relatively high metal density. Accordingly, the layout of the metal features (e.g., traces 126, vias 127, pads 128, etc.) can be used in order to selectively position the depression 125.

In an embodiment, a component 130 may be positioned at least partially within the depression 125. For example, the component 130 is coupled to the package substrate 120 by an interconnect 132, such as a solder. The component 130 may have a thickness C that is greater than the standoff height S. Accordingly, as the electronic system 100 scales to smaller form factors with a reduced standoff height S, components 130 with thicknesses C larger than the standoff height S can still be integrated on the land side of the package substrate 120 (i.e., on the bottom surface of the package substrate 120). In an embodiment, the component 130 may be an electrically passive device, such as a capacitor, an inductor, a resistor, or the like. The component 130 may also be an active electrical component, such as a die or the like.

In an embodiment, the depression 125 may be located at least partially within a footprint of a die 140 that is coupled to the package substrate 120. The die 140 may be coupled to the package substrate 120 through first level interconnects (FLIs) 141, such as solder, hybrid bonding, copper bumps, or the like. Providing the depression 125 at least partially within the footprint of the die 140 may allow for improved power delivery performance. For example, a power deliver component 130 (e.g., a capacitor) may be provided directly below the die 140 in order to reduce a distance between the component 130 and the die 140 to allow for optimal power deliver performance.

Referring now to FIG. 1B, a cross-sectional illustration of an alternative electronic system 100 is shown, in accordance with an additional embodiment. In an embodiment, the electronic system 100 in FIG. 1B is similar to the electronic system 100 in FIG. 1A, with the exception of the location of the depression. Instead of having a depression 125 in the bottom surface of the package substrate 120, a depression 115 is provided into a top surface of the board 110.

As shown, the depression 115 is formed through the inclusion of one or more layers 111 that have a non-uniform thickness. For example, the top three layers 111 have non-uniform thicknesses that provide a depression 115 with a desired depth. The depth of the depression 115 is suitable for accommodating a component 130 that is coupled to the package substrate 120. For example, the component 130 may include a thickness C that is greater than the standoff height S between the board 110 and the package substrate 120. As such, at least a portion of the component 130 may extend down into the depression 115.

In an embodiment, the component 130 in FIG. 1B may be substantially similar to the component 130 in FIG. 1A. That is, the component 130 may be an electrically passive device, such as a capacitor, an inductor, a resistor, or the like. The component 130 may also be an active electrical component, such as a die or the like. The depression 115 and the component 130 may also be located at least partially within a footprint of the die 140 that is coupled to the opposite surface of the package substrate 120. As such, power delivery performance can be optimized.

In an embodiment, the formation of the depression 115 may be implemented with substantially the same processes as those described above with respect to FIG. 1A. For example, a metal density in the region of the board 110 below the depression 115 may be lower than a metal density in the region of the board 110 outside of the depression 115.

Referring now to FIG. 1C, a cross-sectional illustration of an alternative electronic system 100 is shown, in accordance with an additional embodiment. In an embodiment, the electronic system 100 in FIG. 1C is similar to the electronic system 100 in FIG. 1A, with the addition of a second depression 115 in the board 110 below the first depression 125 in the package substrate 120. The combination of a first depression 125 and a second depression 115 allows for an even larger thickness C for the component 130. This provides greater flexibility in the type and/or size of the components 130 that can be integrated between the package substrate 120 and the board 110.

In an embodiment, the first depression 125 and the second depression 115 may be formed with substantially similar manufacturing processes. That is, the depressions 115 and 125 may be formed through control of metal density within the package substrate 120 and the board 110. In the illustrated embodiment, the depth of the first depression 125 is similar to the depth of the second depression 115. Though, in other embodiments, the depths of the first depression 125 and the second depression 115 may be different from each other. Additionally, while the widths of the first depression 125 and the second depression 115 are similar in FIG. 1C, other embodiments may include depressions 125 and 115 that have different widths.

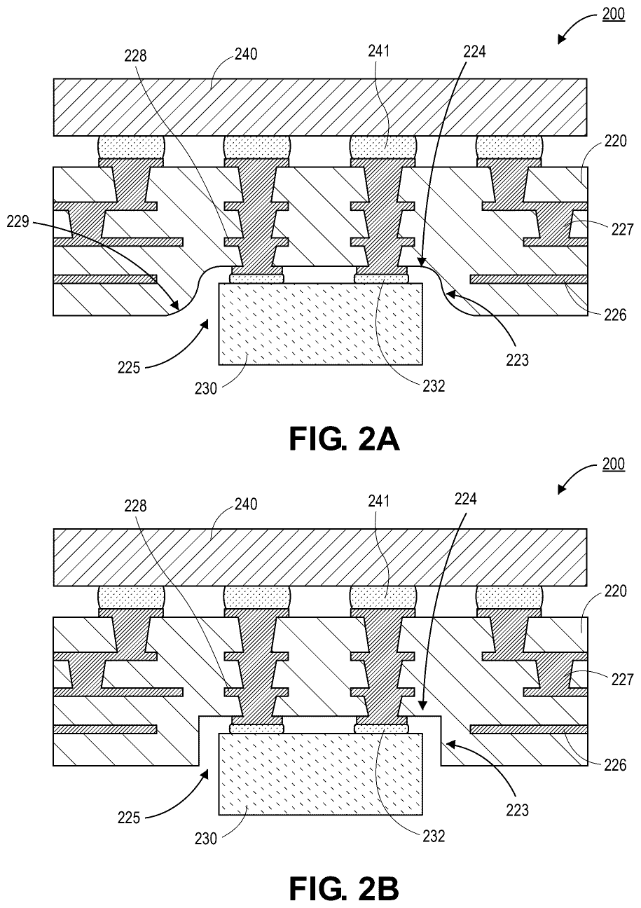

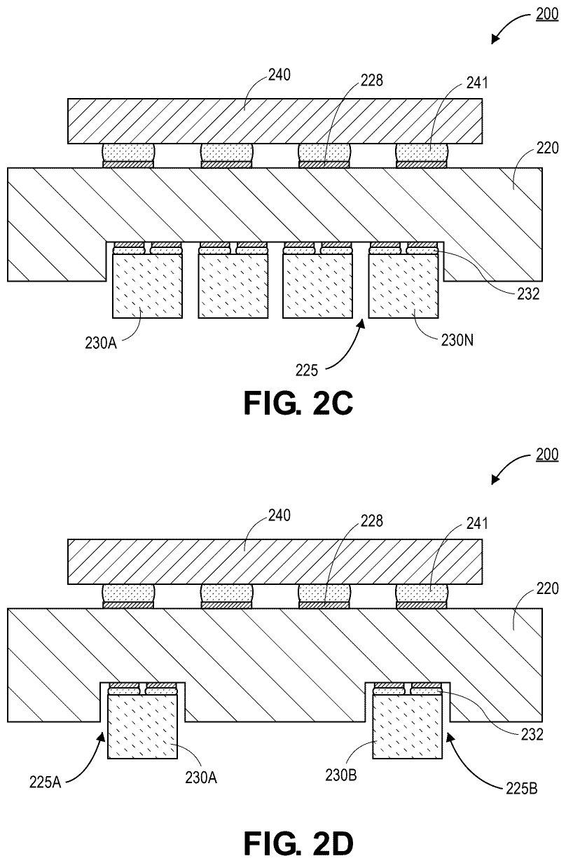

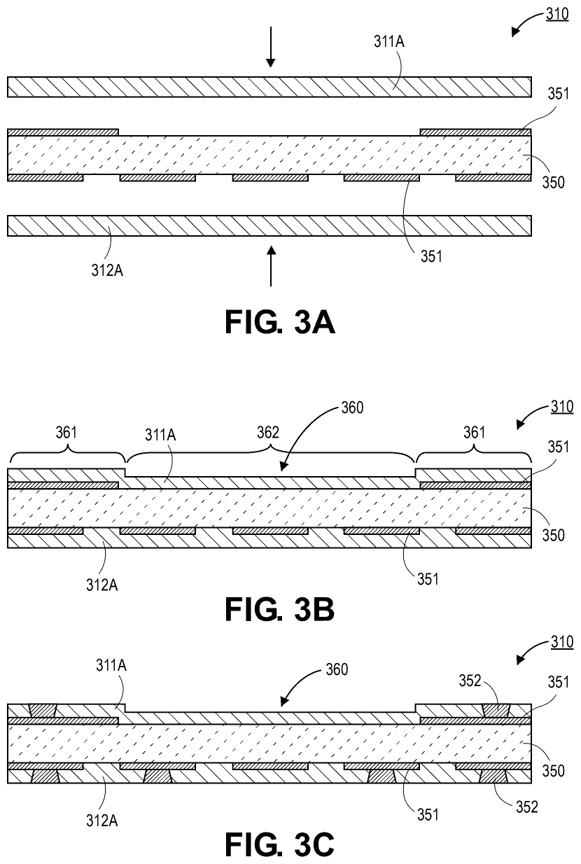

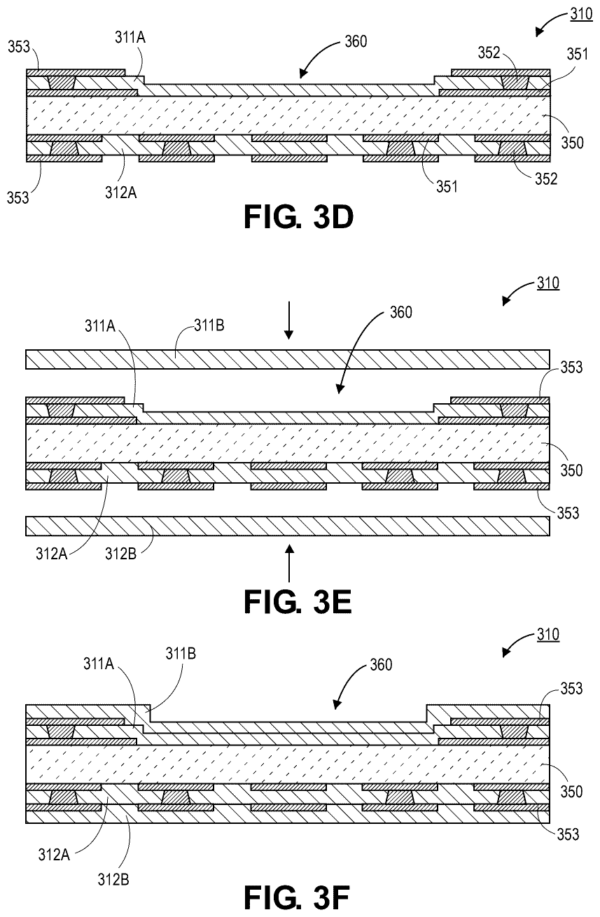

Referring now to FIGS. 2A-2D, a series of cross-sectional illustrations depicting portions of an electronic system 200 is shown, in accordance with various embodiments. In the illustrated embodiments, the electronic systems 200 depict the package substrate 220 with various depression 225 configurations. It is to be appreciated that similar depression configurations may also be manufactured into a board (not shown) that may be coupled to the package substrate 220.

Referring now to FIG. 2A, a cross-sectional illustration of an electronic system 200 with a package substrate 220 that is coupled to a die 240 by interconnects 241 is shown, in accordance with an embodiment. In an embodiment, the package substrate 220 may comprise a plurality of layers (not individually shown in FIG. 2A) that are similar to the layers 121 depicted in FIGS. 1A-1C. Electrical routing (e.g., pads 228, vias 227, traces 226, etc.) may be provided within the package substrate 220. In an embodiment, a depression 225 may be provided into the bottom surface of the package substrate 220. The depression may be the result of a controlled lamination process that provides individual layers with non-uniform thicknesses. A component 230 may be positioned at least partially within the depression 225 and coupled to the package substrate 220 by interconnects 232. The component 230 may be similar to any of the components described in greater detail herein. For example, the component 230 may comprise a capacitor or the like.

In an embodiment, the profile of the depression 225 may be distinct from the profile of cavities that are formed with a subtractive process (e.g., laser or mechanical drilling). For example, the sidewalls 223 may be curved or otherwise non-linear. Further, the transition from the bottom surface of the package substrate 220 to the sidewalls 223 may be a rounded corner 229. Such a rounded corner contrasts from a cavity formed with a subtractive process, which would include a more angular interface between the bottom surface of the package substrate 220 and the sidewalls 223. More generally, the sidewalls 223 may have a profile that provide a gradual transition from the bottom surface of the package substrate 220 to a bottom surface 224 of the depression 225. In some embodiments, the bottom surface 224 of the depression 225 may be substantially planar. For example, the bottom surface 224 of the depression 225 may be substantially parallel to the bottom surface of the package substrate 220. Though, it is to be appreciated that manufacturing tolerances may result in slight differences in the angle of the two surfaces relative to each other, and/or the entirety of the bottom surface 224 of the depression 225 may not be perfectly parallel with the bottom surface of the package substrate 220.

Referring now to FIG. 2B, a cross-sectional illustration of a portion of an electronic system 200 is shown, in accordance with an alternative embodiment. The electronic system 200 in FIG. 2B may be substantially similar to the electronic system 200 in FIG. 2A, with the exception of the profile of the depression 225. Instead of having curved and/or sloping sidewalls 223, the sidewalls 223 in FIG. 2B may be substantially vertical. A more vertical sidewall 223 profile may be enabled through control of the metal density within the package substrate 220 during the lamination processes used to build up the package substrate 220. More generally, a more vertical sidewall 223 profile is distinguishable from the cavity sidewall profiles provided in laser drilling processes where a substantially linear and tapered sidewall profile would be expected. While shown with angular corners, in some embodiments, the corners of the depression 225 may be rounded (e.g., more rounded than a typical drilling process would allow for). The rounding of the corners may be expected since subsequent layers are laminated over each other and may have some degree of “flow” during the lamination process.

Referring now to FIG. 2C, a cross-sectional illustration of a portion of an electronic system 200 is shown, in accordance with an additional embodiment. In an embodiment, the electronic system 200 in FIG. 2C is similar to the electronic system 200 in FIG. 2B, with the exception of there being a plurality of components 230A-230N provided within a single depression 225. That is, a width of the depression 225 may be sufficient to house multiple components 230 below the die 240. In an embodiment, the plurality of components 230A-230N may comprise the same component (e.g., all of the components 230 may be capacitors), or the plurality of components 230A-230N may comprise two or more different types of components (e.g., active devices, passive devices, etc.). In the embodiment shown in FIG. 2C, the depression 225 has vertical sidewalls similar to those described with respect to FIG. 2B. However, it is to be appreciated that the depression 225 may also include sloped sidewalls and/or rounded corners, similar to the depression 225 described with respect to FIG. 2A.

Referring now to FIG. 2D, a cross-sectional illustration of a portion of an electronic system 200 is shown, in accordance with an additional embodiment. In an embodiment, the electronic system 200 in FIG. 2D is similar to the electronic system 200 in FIG. 2B, with the exception of there being a plurality of components 230A and 230B provided within a plurality of depressions 225A and 225B. For example, the component 230A may be located in the depression 225A, and the component 230B may be located in the depression 225B. In an embodiment, both depressions 225A and 225B may be at least partially within a footprint of the die 240. Though, one or both of the depressions 225A and/or 225B may be outside of the footprint of the die 240. In an embodiment, the plurality of components 230A and 230B may comprise the same component (e.g., both components 230A and 230B may be capacitors), or the components 230A and 230B may comprise different types of components (e.g., active devices, passive devices, etc.). In the embodiment shown in FIG. 2D, the depressions 225A and 225B have vertical sidewalls similar to those described with respect to FIG. 2B. However, it is to be appreciated that the depressions 225A and/or 225B may also include sloped sidewalls and/or rounded corners, similar to the depression 225 described with respect to FIG. 2A.

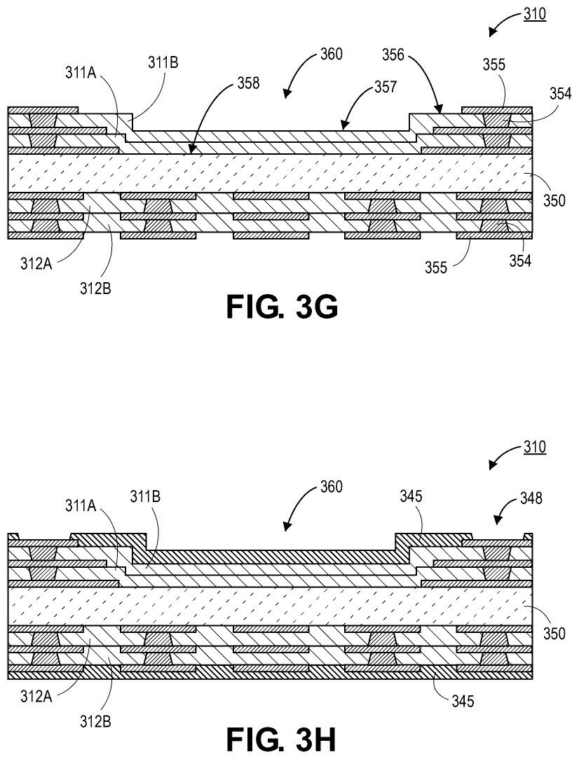

Referring now to FIGS. 3A-3H, a series of cross-sectional illustrations depicting a process for forming a board 310 with a depression for accommodating a component is shown, in accordance with an embodiment. In the illustrated embodiments, the formation of the board 310 is used as an exemplary embodiment. It is to be appreciated that similar laminating processes with controlled metal densities can be used in order to fabricate a package substrate with a depression as well.

Referring now to FIG. 3A, a cross-sectional illustration of a portion of a board 310 is shown, in accordance with an embodiment. In an embodiment, the board 310 may comprise a core 350. The core 350 may be an organic core with fiber reinforcement (e.g., glass fibers). The core 350 may also be a glass core in some embodiments. In an embodiment, a first metal layer 351 may be provided over a top surface and a bottom surface of the core 350. The first metal layer 351 may comprise copper or any other suitable electrically conductive material. The first metal layer 351 may comprise pads, traces, and/or the like.

As shown in FIG. 3A, an upper first layer 311A and a lower first layer 312A are positioned over the core 350. As indicated by the arrows, the upper first layer 311A and the lower first layer 312A are applied over the core 350. For example, a lamination process may be used in some embodiments. The upper first layer 311A and the lower first layer 312A may be dielectric materials, such as a buildup film or the like.

Referring now to FIG. 3B, a cross-sectional illustration of the board 310 after the upper first layer 311A and the lower first layer 312A are laminated onto the board 310 is shown, in accordance with an embodiment. As show, the lower first layer 312A has a substantially flat bottom surface. This is due, at least in part, to a substantially uniform metal density of the first metal layer 351 across the bottom surface of the core 350. In contrast, the upper first layer 311A has a depression 360. A first region 361 of the board 310 has a first metal density in the first metal layer 351, and a second region 362 of the board 310 has a second metal density in the first metal layer 351. For example, the second region 362 may not include any metal in some embodiments. More generally, the first metal density is higher than the second metal density. Due to the differences in metal density, the upper first layer 311A forms a depression 360 during the lamination process. Stated differently, a first proportion of metal (i.e., the total area of metal in the first metal layer 351 relative to the combined area of the upper first layer 311A and the metal in the first metal layer 351) within a cross-section of the first region 361 is higher than a second proportion of metal (i.e., the total area of metal in the first metal layer 351 relative to the combined area of the upper first layer 311A and the metal in the first metal layer 351) within a cross-section of the second region 362. In some embodiments, the dielectric material for the upper first layer 311A may have a relatively high fiber and resin content to reduce flow of the upper first layer 311A during lamination in order to preserve the shape of the depression 360.

Referring now to FIG. 3C, a cross-sectional illustration of the board 310 after the formation of vias 352 over the first metal layer 351 (on the top and bottom of the board 310) is shown, in accordance with an embodiment. In an embodiment, the vias 352 may be formed with a laser drilling process followed by a plating process.

Referring now to FIG. 3D, a cross-sectional illustration of the board 310 after the formation of a second metal layer 353 on the top and bottom of the board 310 is shown, in accordance with an embodiment. The second metal layer 353 may be plated up and patterned, or a damascene process can be used with a photoresist (not shown). In an embodiment, the metal densities of the second metal layer 353 over the upper first layer 311A and the lower first layer 312A may be similar to the metal densities provided over the core 350.

Referring now to FIG. 3E, a cross-sectional illustration of the board 310 while an upper second layer 311B and a lower second layer 312B are applied to the board 310 is shown, in accordance with an embodiment. In an embodiment, the upper second layer 311B and the lower second layer 312B may be dielectric materials that are similar to (or the same as) the upper first layer 311A and the lower first layer 312A. For example, the upper second layer 311B and the lower second layer 312B may comprise a buildup film or the like. In an embodiment, the upper second layer 311B and the lower second layer 312B may be applied with a lamination process or the like.

Referring now to FIG. 3F, a cross-sectional illustration of the board 310 after the upper second layer 311B and the lower second layer 312B have been laminated onto the board 310 is shown, in accordance with an embodiment. As shown, the lower second layer 312B has a planar bottom surface since the metal density of the second metal layer 353 is consistent across the lower first layer 312A. The upper second layer 311B retains the depression 360 due to the non-uniform metal density of the second metal layer 353 across the upper first layer 311A. The depth of the depression 360 in FIG. 3F may be greater than the depth of the depression 360 in FIG. 3D due to the combination of stacking multiple upper layers 311A and 311B that both have non-uniform thicknesses.

In the illustrated embodiment, the depression 360 has substantially vertical sidewalls, similar to the embodiment shown in FIG. 2B. However, in other embodiments, the process shown in FIGS. 3A-3H may result in the formation of a depression 360 that has a profile more similar to the depression shown in FIG. 2A. That is, the depression 360 may have rounded corners and sidewalls that are curved and/or tapered.

Referring now to FIG. 3G, a cross-sectional illustration of the board 310 after vias 354 and a third metal layer 355 are formed is shown, in accordance with an embodiment. The vias 354 and the third metal layer 355 may be formed with any suitable patterning and plating processes. In the process flow of FIGS. 3A-3H, the third metal layer 355 is the outermost metal layer. Other embodiments may include the formation of additional dielectric layers and metal layers. For example, five or more dielectric layers, or seven or more dielectric layers may be used to form the board 310. More particularly, it is to be appreciated that the number of dielectric layers between the bottom of the depression 360 and the core 350 is equal to the total number of dielectric layers over the core 350 at locations outside of the depression 360. That is, the depression 360 is formed without the removal of any layers using a subtractive process.

As noted above, the upper layers 311A and 311B may be laminated over the core 350 in order to form a depression 360. In some embodiments, the depression 360 may be defined by a dielectric layer (e.g., a combination of the upper first layer 311A and the upper second layer 311B) having a non-uniform thickness. For example, the dielectric layer may have a thickness between a first surface 356 and a top surface 358 of the core 350 that is larger than a thickness between a second surface 357 (i.e., within the depression 360) and the top surface 358 of the core 350. Stated differently, a first region of the board 310 with a higher metal density may have a dielectric thickness that is greater than a dielectric thickness of a second region of the board 310 with a lower metal density. The difference in thickness provides the profile of the depression 360.

Referring now to FIG. 3H, a cross-sectional illustration of the board 310 after a solder resist 345 is applied over the top and/or bottom surfaces of the board 310 is shown, in accordance with an embodiment. In an embodiment, the solder resist 345 may be patterned to form openings 348 over pads. In a subsequent operation (not shown), a package substrate may be coupled to the pads exposed by the openings 348 by interconnects (e.g., solder or the like). As shown, the solder resist 345 may substantially conform to the upper second layer 311B in order to maintain the depression 360.

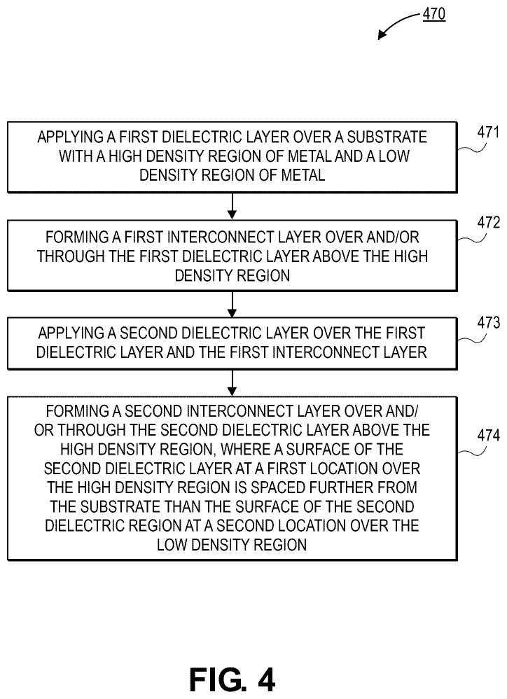

Referring now to FIG. 4, a process flow diagram of a process 470 for forming a substrate with a depression is shown, in accordance with an embodiment. In an embodiment, the substrate may be a board, such as a PCB, a package substrate, or the like. In an embodiment, the process may begin with operation 471, which comprises applying a first dielectric layer over a substrate with a high density region of metal and a low density region of metal. The first dielectric layer may be applied over the substrate with a lamination process or the like. In an embodiment, the substrate may be an organic core, a glass core, or the like. The substrate may also refer to one or more layers of dielectric material that are similar to or the same as the first dielectric layer. That is, in some embodiments, the substrate is coreless.

In an embodiment, the high density region of metal may be an outer region of the substrate, and the low density region of metal may be towards a center of the substrate. Though, the high density region and the low density region may be provided at any location on the substrate. In an embodiment, the low density region of metal may comprise no metal or substantially no metal. The metal in high density region and/or the low density region may comprise pads, traces, planes, and/or the like.

In an embodiment, the process 470 may continue with operation 472, which comprises forming a first interconnect layer over and/or through the first dielectric layer above the high density region. The first interconnect layer may comprise vias through at least a portion of the first dielectric layer, pads over the first dielectric layer, traces over the first dielectric layer, and/or the like. The first interconnect layer may be formed with any suitable plating and/or patterning processes.

In an embodiment, the process 470 may continue with operation 473, which comprises applying a second dielectric layer over the first dielectric layer and the first interconnect layer. In an embodiment, the second dielectric layer may be substantially similar to the first dielectric layer. The second dielectric layer may be applied with a lamination process or the like.

In an embodiment, the process 470 may continue with operation 474, which comprises forming a second interconnect layer over and/or through the second dielectric layer above the high density region. In an embodiment, a surface of the second dielectric layer at a first location over the high density region is spaced further form the substrate than the surface of the second dielectric region at a second location over the low density region. This provides a depression within at least the second dielectric layer. The depression may be similar to any of the depressions described in greater detail herein. For example, the depression may be similar to any of the ones described in FIG. 2A-2D. In an embodiment, the depression is the result of the uneven metal density across the substrate. As the low density regions allow for portions of the first and/or second dielectric layer to be pressed down further than the portions over the high density regions. Accordingly, the location and depth of the depression can be controlled by the distribution of the metal on the substrate.

In other embodiments, the process may continue with the attachment of a component (e.g., a passive component or an active component) at least partially within the depression. The component can be coupled to the substrate, or the component may be provided on a second substrate that opposes the substrate.

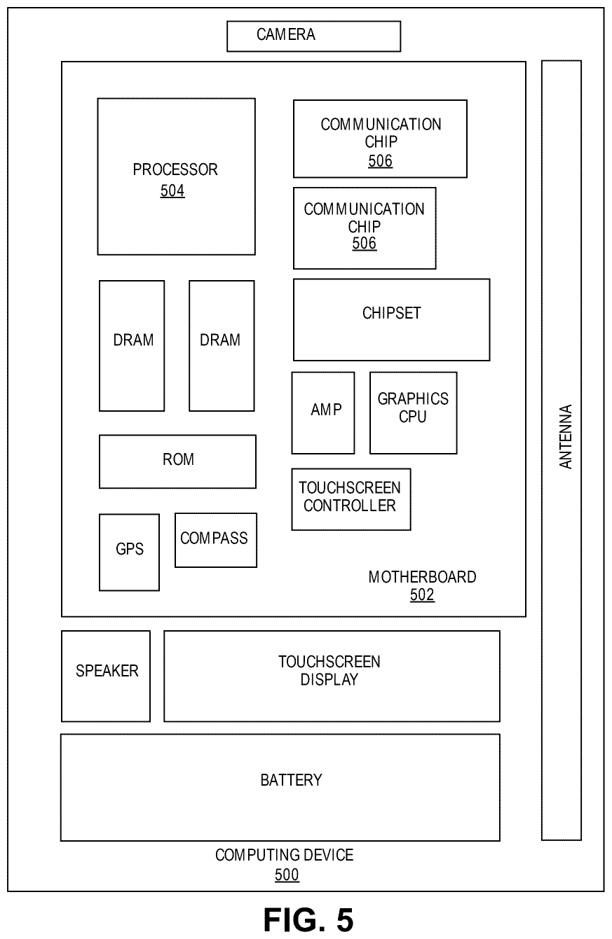

FIG. 5 illustrates a computing device 500 in accordance with one implementation of the disclosure. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the disclosure, the integrated circuit die of the processor may be part of an electronic package that comprises a package substrate and/or a board with a recess for accommodating a land side component, such as a land side capacitor, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the disclosure, the integrated circuit die of the communication chip may be part of an electronic package that comprises a package substrate and/or a board with a recess for accommodating a land side component, such as a land side capacitor, in accordance with embodiments described herein.

In an embodiment, the computing device 500 may be part of any apparatus. For example, the computing device may be part of a personal computer, a server, a mobile device, a tablet, an automobile, or the like. That is, the computing device 500 is not limited to being used for any particular type of system, and the computing device 500 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first surface and a second surface, wherein the substrate comprises a dielectric material; a first region of the substrate with a first metal density; a second region of the substrate with a second metal density, wherein the second metal density is lower than the first metal density; and a depression into the first surface of the substrate, wherein the depression is located at least partially over the second region of the substrate.

Example 2: the apparatus of Example 1, wherein the depression has tapered sidewalls or vertical sidewalls.

Example 3: the apparatus of Example 1 or Example 2, wherein the depression has rounded corners.

Example 4: the apparatus of Examples 1-3, wherein the substrate comprises a plurality of layers, and wherein at least one of the plurality of layers has a first thickness over the first region and a second thickness over the second region, wherein the second thickness is smaller than the first thickness.

Example 5: the apparatus of Examples 1-4, wherein a depth of the depression is at least 10 μm.

Example 6: the apparatus of Examples 1-5, wherein the depression has a substantially planar surface that is substantially parallel to the second surface.

Example 7: the apparatus of Examples 1-6, further comprising: a component within the depression and coupled to the substrate.

Example 8: the apparatus of Example 7, wherein the component is an electrically passive component.

Example 9: the apparatus of Example 7 or Example 8, further comprising: a die coupled to the second surface of the substrate.

Example 10: the apparatus of Example 9, wherein the component is at least partially within a footprint of the die.

Example 11: an apparatus, comprising: a first substrate; a second substrate coupled to the first substrate by an interconnect, wherein a standoff height is provided between the first substrate and the second substrate; a depression with rounded corners in the first substrate; and a component between the first substrate and the second substrate, wherein a thickness of the component is greater than the standoff height, and wherein the component is within a footprint of the depression.

Example 12: the apparatus of Example 11, wherein the first substrate is a package substrate, and wherein the second substrate is a board.

Example 13: the apparatus of Example 11 or Example 12, wherein the first substrate is a board, and wherein the second substrate is a package substrate.

Example 14: the apparatus of Examples 11-13, further comprising: a second depression in the second substrate, wherein the component is within the depression and the second depression.

Example 15: the apparatus of Examples 11-14, wherein the first substrate has a first metal density outside of the footprint of the depression and a second metal density within the footprint of the depression, wherein the second metal density is lower than the first metal density.

Example 16: the apparatus of Examples 11-15, wherein sidewalls of the depression are non-linear.

Example 17: the apparatus of Examples 11-16, wherein the component is an electrically passive component.

Example 18: an apparatus, comprising: a substrate with a first region and a second region, wherein the substrate comprises a dielectric material; electrically conductive routing within the substrate, wherein the electrically conductive routing within the first region has a first proportion of metal area relative to the dielectric material area, and the electrically conductive routing within the second region has a second proportion of metal area relative to the dielectric material area, and wherein the second proportion is lower than the first proportion; and wherein the first region of the substrate has a first thickness, and the second region of the substrate has a second thickness that is smaller than the first thickness.

Example 19: the apparatus of Example 18, wherein the substrate comprises a plurality of dielectric layers, and wherein a first number of the plurality of dielectric layers in the first region is equal to a second number of the plurality of dielectric layers in the second region.

Example 20: the apparatus of Example 18 or Example 19, wherein the substrate has a first surface and a second surface opposite from the first surface, wherein the first surface is substantially planar, and wherein the second surface comprises a depression.

What is claimed is:

1. An apparatus, comprising:
a substrate with a first surface and a second surface, wherein the substrate comprises a dielectric material;
a first region of the substrate with a first metal density;
a second region of the substrate with a second metal density, wherein the second metal density is lower than the first metal density; and
a depression into the first surface of the substrate, wherein the depression is located at least partially over the second region of the substrate.

2. The apparatus of claim 1, wherein the depression has tapered sidewalls or vertical sidewalls.

3. The apparatus of claim 1, wherein the depression has rounded corners.

4. The apparatus of claim 1, wherein the substrate comprises a plurality of layers, and wherein at least one of the plurality of layers has a first thickness over the first region and a second thickness over the second region, wherein the second thickness is smaller than the first thickness.

5. The apparatus of claim 1, wherein a depth of the depression is at least 10 μm.

6. The apparatus of claim 1, wherein the depression has a substantially planar surface that is substantially parallel to the second surface.

7. The apparatus of claim 1, further comprising:
a component within the depression and coupled to the substrate.

8. The apparatus of claim 7, wherein the component is an electrically passive component.

9. The apparatus of claim 7, further comprising:
a die coupled to the second surface of the substrate.

10. The apparatus of claim 9, wherein the component is at least partially within a footprint of the die.

11. An apparatus, comprising:
a first substrate;
a second substrate coupled to the first substrate by an interconnect, wherein a standoff height is provided between the first substrate and the second substrate;
a depression with rounded corners in the first substrate; and
a component between the first substrate and the second substrate, wherein a thickness of the component is greater than the standoff height, and wherein the component is within a footprint of the depression.

12. The apparatus of claim 11, wherein the first substrate is a package substrate, and wherein the second substrate is a board.

13. The apparatus of claim 11, wherein the first substrate is a board, and wherein the second substrate is a package substrate.

14. The apparatus of claim 11, further comprising:
a second depression in the second substrate, wherein the component is within the depression and the second depression.

15. The apparatus of claim 11, wherein the first substrate has a first metal density outside of the footprint of the depression and a second metal density within the footprint of the depression, wherein the second metal density is lower than the first metal density.

16. The apparatus of claim 11, wherein sidewalls of the depression are non-linear.

17. The apparatus of claim 11, wherein the component is an electrically passive component.

18. An apparatus, comprising:
a substrate with a first region and a second region, wherein the substrate comprises a dielectric material;
electrically conductive routing within the substrate, wherein the electrically conductive routing within the first region has a first proportion of metal area relative to the dielectric material area, and the electrically conductive routing within the second region has a second proportion of metal area relative to the dielectric material area, and wherein the second proportion is lower than the first proportion; and
wherein the first region of the substrate has a first thickness, and the second region of the substrate has a second thickness that is smaller than the first thickness.

19. The apparatus of claim 18, wherein the substrate comprises a plurality of dielectric layers, and wherein a first number of the plurality of dielectric layers in the first region is equal to a second number of the plurality of dielectric layers in the second region.

20. The apparatus of claim 18, wherein the substrate has a first surface and a second surface opposite from the first surface, wherein the first surface is substantially planar, and wherein the second surface comprises a depression.
